(19) United States
(12) Patent Application Publication
(10) Pub. No.: US 2013/0260109 A1
(43) Pub. Date: Oct. 3, 2013

(54) PHOTOCURABLE RESIN COMPOSITION, DRY FILM, CURED PRODUCT AND PRINTED WIRING BOARD

(71) Applicant: TAIYO INK MFG. CO., LTD., Hiki-gun (JP)

(72) Inventors: Manabu Akiyama, Hiki-gun (JP); Yoko Shibasaki, Hiki-gun (JP); Shoji Minegishi, Hiki-gun (JP)

(73) Assignee: TAIYO INK MFG. CO., LTD., Hiki-gun (JP)

(21) Appl. No.: 13/827,072

(22) Filed: Mar. 14, 2013

(30) Foreign Application Priority Data
Mar. 30, 2012 (JP) 2012-081851
Jun. 20, 2012 (JP) 2012-138826

(51) Int. Cl. G03F 7/029; H05K 1/03

(52) U.S. Cl. CPC G03F 7/029; H05K 1/0373
USPC 428/195.1; 430/280.1; 174/255

(57) ABSTRACT

[Problems] The present invention provides a photocurable resin composition having excellent adhesion with a substrate and excellent resolution; a film obtained by using the photocurable resin composition; a cured product obtained by curing the photocurable resin composition; and a printed wiring board comprising the cured product.

[Means for Solution] The photocurable resin composition according to the present invention is characterized by comprising (A) a carboxyl group-containing resin, (B) an acylphosphine oxide-based photopolymerization initiator, (C) a titanocene-based photopolymerization initiator, (D) a photosensitive monomer and (E) a polymerization inhibitor.

### TECHNICAL FIELD

The present invention relates to a photocurable resin composition, a dry film, a cured product and a printed wiring board.

### BACKGROUND ART

In recent years, as an insulation material of solder resists and the like for consumer and industrial printed wiring boards, from the standpoint of attaining high precision and high density, liquid developing-type curable resin compositions that are, upon being irradiated with UV light, developed to form an image and then subjected to final curing (main curing) by at least either of heating and irradiation with light have been employed.

Among such liquid developing-type curable resin compositions, in consideration of environmental problems, the prevailing trend is the use of an alkali developing-type photocurable resin composition which utilizes an aqueous alkaline solution its developing solution. As such an alkali developing-type photocurable resin composition, one containing an epoxy acrylate-modified resin derived by modification of an epoxy resin as a main component has been commonly employed.

For example, Patent Document 1 discloses a solder resist composition which comprises a photosensitive resin obtained by adding an acid anhydride to a reaction product of a novolac-type epoxy compound and an unsaturated monobasic acid, a photopolymerization initiator, a diluent and an epoxy compound. Patent Document 2 discloses a solder resist composition which comprises: a photosensitive resin which was obtained by adding (meth)acrylic acid to an epoxy resin produced by allowing a reaction product of a salicyl aldehyde and a monohydric phenol to react with epichlorohydrin and further allowing the resultant to react with a polybasic carboxylic acid or an anhydride thereof; a photopolymerization inhibitor; an organic solvent and the like.

Further, in response to densification of printed wiring boards associated with miniaturization of electronic devices, a curable resin composition with improved workability and performance has been demanded. Particularly, recent years have seen progress in fine-patterning of substrate wirings and there are now seen patterns of L/S=10 μm/10 μm or less; therefore, solder resists are also demanded to have performance corresponding to such fine patterns.

### RELATED ART DOCUMENTS

### Patent Documents

[Patent Document 1] Japanese Unexamined Patent Application Publication No. S61-243869 (Claims)
[Patent Document 2] Japanese Unexamined Patent Application Publication No. H3-250012 (Claims)

### SUMMARY OF THE INVENTION

### Problems to be Solved by the Invention

In such a fine-pitched wiring pattern described in the above, the effects of irregular substrate surface are more apparent and, on a rough surface, a wiring pattern may not be formed upright or the base of a wiring pattern may be disrupted by etching, causing the pattern to be collapsed. Therefore, in the case of forming a fine-pitched wiring pattern on a substrate, in order to ensure the stability of the wiring pattern, a substrate having a smooth surface is preferably employed.

However, when an insulation layer such solder resist is formed on a substrate having a smooth surface, there are problems in that the adhesion between the substrate and the insulation layer is poor and that the insulation layer may be detached to be in a loose condition. Furthermore, in response to fine-patterning of wirings, insulation layers such as solder resists are demanded to have a high resolution.

Therefore, an object of the present invention is to provide a photocurable resin composition having excellent adhesion with a substrate and excellent resolution; a film obtained by using the photocurable resin composition; a cured product obtained by cuing the photocurable resin composition; and a printed wiring board comprising the cured product.

### Means for Solving the Problems

The present inventors intensively studied in order to solve the above-described problems and discovered that a photocurable resin composition comprising a titanocene-based photopolymerization initiator has excellent resolution and excellent adhesion with a substrate and that, even when it is coated on a substrate having a smooth surface to form an insulation layer, detachment and loosening thereof can be inhibited. However, since a titanocene-based photopolymerization initiator exhibits absorption and reactivity for visible light as well, a photopolymerizable resin composition containing only a titanocene-based photopolymerization initiator as a photopolymerization initiator had problems in that its stability is poor and that it undergoes polymerization reaction even under a yellow lamp in which shorter wavelengths are eliminated. Thus, the present inventors further studied to discover that, by using a titanocene-based photopolymerization initiator, an acylphosphine oxide-based photopolymerization initiator and a polymerization inhibitor in combination, the above-described problems can be solved along with the problem of stability in working environment, thereby completing the present invention.

That is, the photocurable resin composition according to the present invention is characterized by comprising (A) a carboxyl group-containing resin, (B) an acylphosphine oxide-based photopolymerization initiator, (C) a titanocene-based photopolymerization initiator, (D) a photosensitive monomer and (E) a polymerization inhibitor.

In the photocurable resin composition according to the present invention, it is preferred that the above-described (B) acylphosphine oxide-based photopolymerization initiator be a compound having a partial structure represented by the following Formula (I):

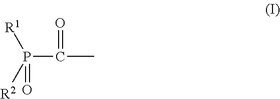

(wherein, R¹ and R² each independently represent a halogen atom, a linear or branched alkyl group having 1 to 6 carbon atoms, a linear or branched alkoxy group having 1 to 6 carbon atoms, a cycloalkyl group having 5 to 20 carbon atoms, an aryl group having 6 to 20 carbon atoms which is optionally substituted with at least one of alkyl groups and alkoxy groups, or an arylcarbonyl group having 7 to 20 carbon atoms which is optionally substituted with at least one of alkyl groups and alkoxy groups).

Further, in the photocurable resin composition according to the present invention, it is preferred that the above-described (C) titanocene-based photopolymerization initiator be a compound represented by the following Formula (II):

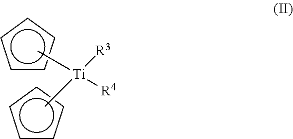

(wherein, R³ and R⁴ each independently represent an aryl group having 6 to 20 carbon atoms which is optionally substituted with at least one selected from halogen atoms, alkyl groups, alkoxy groups, alkylcarbonyl groups, alkoxyalkylcarbonyl groups, aryl groups and heterocyclic groups).

Further, in the photocurable resin composition according to the present invention, it is preferred that the above-described (C) titanocene-based photopolymerization initiator be a compound represented by the following formula:

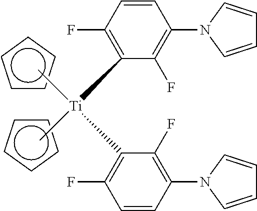

Further, in the photocurable resin composition according to the present invention, it is preferred that the above-described (E) polymerization inhibitor contain at least one of naphthalene derivatives, naphthoquinones and naphthoquinone derivatives.

Further, in the photocurable resin composition according to the present invention, it is preferred that the above-described (A) carboxyl group-containing resin contain a carboxyl group-containing resin obtained by using a phenol compound as a starting material.

The dry film according to the present invention is characterized by being obtained by coating and drying any one of the above-described photocurable resin compositions on a film.

The cured product according to the present invention is characterized by being obtained by curing any one of the above-described photocurable resin compositions or the above-described dry film.

The printed wiring board according to the present invention is characterized by comprising the above-described cured product.

### Effects of the Invention

According to the present invention, a photocurable resin composition which has excellent adhesion with a substrate and excellent resolution as well as stability in working environment and HAST resistance; a film obtained by using the photocurable resin composition; a cured product obtained by curing the photocurable resin composition; and a printed wiring board comprising the cured product can be provided.

### BRIEF DESCRIPTION OF THE DRAWINGS

FIG. 1 is a photograph showing a condition where no peeling was observed in the evaluation of adhesion in an example.

FIG. 2 is a photograph showing a condition where peeling was observed in the evaluation of adhesion in an example.

### MODE FOR CARRYING OUT THE INVENTION

The photocurable resin composition according to the present invention is characterized by comprising (A) a carboxyl group-containing resin, (B) an acylphosphine oxide-based photopolymerization initiator, (C) a titanocene-based photopolymerization initiator, (D) a photosensitive monomer and (E) a polymerization inhibitor. By adopting the above-described constitution, a photocurable resin composition which has excellent adhesion with a substrate and excellent resolution as well as stability in working environment can be attained. Here, the term “stability in working environment” refers to a property that the curing reaction of the photocurable resin composition does not progress or the progress thereof is suppressed in a condition where the photocurable resin composition is illuminated under a yellow lamp having no shorter wavelength and is not exposed to ultraviolet light.

The above-described components of the photocurable resin composition will now each be described in detail.

### [(A) Carboxyl Group-Containing Resin]

In the present invention, as the (A) carboxyl group-containing resin, a variety of conventionally known carboxyl group-containing resin having a carboxyl group in the molecule may be employed. In particular, from the standpoints of photocurability and resolution, a carboxyl group-containing photosensitive resin having an ethylenically unsaturated double bond in the molecule is preferred. It is preferred that the ethylenically unsaturated double bond be originated from acrylic acid, methacrylic acid or a derivative thereof.

Specific examples of the carboxyl group-containing resin include the following compounds (that may each be either an oligomer or a polymer).

(1) A carboxyl group-containing photosensitive resin prepared by allowing a reaction product, which is obtained by a reaction between a compound having a plurality of phenolic hydroxyl groups in one molecule and an alkylene oxide such as ethylene oxide or propylene oxide, to react with an unsaturated group-containing monocarboxylic acid and then allowing the thus obtained reaction product to react with a polybasic acid anhydride.

(2) A carboxyl group-containing photosensitive resin prepared by allowing the later-described multifunctional (solid) epoxy resin, which has two or more functional groups, to react with (meth)acrylic acid and then adding a dibasic acid anhydride to a hydroxyl group existing in the side chain of the resultant.

(3) A carboxyl group-containing photosensitive resin prepared by allowing a multifunctional epoxy resin, which is obtained by further epoxidizing a hydroxyl group of the later-described bifunctional (solid) epoxy resin with epichlorohydrin, to react with (meth)acrylic acid and then adding a dibasic acid anhydride to the resulting hydroxyl group.

(4) A carboxyl group-containing photosensitive resin prepared by allowing a reaction product, which is obtained by a reaction between a compound having a plurality of phenolic hydroxyl groups in one molecule and a cyclic carbonate compound such as ethylene carbonate or propylene carbonate, to react with an unsaturated group-containing monocarboxylic acid and then allowing the thus obtained reaction product to react with a polybasic acid anhydride.

(5) A carboxyl group-containing photosensitive urethane resin obtained by a polyaddition reaction of a diisocyanate; a (meth)acrylate or partial acid anhydride-modified product of a bifunctional epoxy resin such as a bisphenol A-type epoxy resin, a hydrogenated bisphenol A-type epoxy resin, a bisphenol F-type epoxy resin, a bisphenol S-type epoxy resin, a bixylenol-type epoxy resin or a biphenol-type epoxy resin; a carboxyl group-containing dialcohol compound; and a diol compound.

(6) A carboxyl group-containing non-photosensitive resin obtained by copolymerization of an unsaturated carboxylic acid such as (meth)acrylic acid and an unsaturated group-containing compound such as styrene, α-methylstyrene, a lower alkyl (meth)acrylate or isobutylene.

(7) A carboxyl group-containing non-photosensitive urethane resin obtained by a polyaddition reaction of a diisocyanate (e.g. an aliphatic diisocyanate, a branched aliphatic diisocyanate, an alicyclic diisocyanate or an aromatic diisocyanate), a carboxyl group-containing dialcohol compound (e.g. dimethylol propionic acid or dimethylol butanoic acid) and a diol compound (e.g. a polycarbonate-based polyol, a polyether-based polyol, a polyester-based polyol, a polyolefin-based polyol, an acrylic polyol, a bisphenol A-type alkylene oxide adduct diol or a compound having a phenolic hydroxyl group and an alcoholic hydroxyl group).

(8) A carboxyl group-containing non-photosensitive polyester resin prepared by allowing the later-described bifunctional oxetane resin to react with a dicarboxylic acid such as adipic acid, phthalic acid or hexahydrophthalic acid and then adding a dibasic acid anhydride, such as phthalic anhydride, tetrahydrophthalic anhydride or hexahydrophthalic anhydride, to the resulting primary hydroxyl group.

(9) A carboxyl group-containing photosensitive urethane resin having a (meth)acrylated terminal, which is obtained by adding a compound having one hydroxyl group and one or more (meth)acryloyl groups in the molecule, such as hydroxyalkyl (meth)acrylate, during the synthesis of the resin described in the above (5) or (7).

(10) A carboxyl group-containing photosensitive urethane resin having a (meth)acrylated terminal, which is obtained by adding a compound having one isocyanate group and one or more (meth)acryloyl groups in the molecule, such as an equimolar reaction product of isophorone diisocyanate and pentaerythritol triacrylate, during the synthesis of the resin described in the above (5) or (7).

(11) A carboxyl group-containing photosensitive resin obtained by further adding a compound having one epoxy group and one or more (meth)acryloyl groups in one molecule to any one of the resins described in the above (1) to (10).

Here, the term “(meth)acrylate” used herein is a general term for acrylates, methacrylates and mixtures thereof and this is hereinafter applicable to all similar expressions.

Since such carboxyl group-containing resins described in the above have a number of carboxyl groups in the side chain of the backbone polymer, they can be developed with a dilute aqueous alkaline solution.

Further, the above-described carboxyl group-containing resin has an acid value in the range of appropriately 40 to 200 mg KOH/g, more preferably 45 to 120 mg KOH/g. When the acid value of the carboxyl group-containing resin is less than 40 mg KOH/g, development with an alkali may become difficult. Meanwhile, when the acid value is higher than 200 mg KOH/g, since the developing solution further dissolves an exposed part, the resulting lines may become excessively thin and in some cases, the exposed and non-exposed parts may be indistinctively dissolved and detached by the developing solution, making it difficult to draw a normal resist pattern; therefore, such an acid value is not preferred.

Further, the weight average molecular weight of the above-described carboxyl group-containing resin varies depending on the resin skeleton; however, in general, it is preferably in the range of 2,000 to 150,000, more preferably in the range of 5,000 to 100,000. When the weight average molecular weight is less than 2,000, the tack-free performance may be poor and the moisture resistance of the resulting coating film after exposure may be deteriorated to cause a reduction in the film during development, which may greatly impair the resolution. Meanwhile, when the weight average molecular weight exceeds 150,000, the developing property may be markedly deteriorated and the storage stability may be impaired.

The content of such carboxyl group-containing resin is in the range of appropriately 20 to 60% by mass, preferably 30 to 50% by mass, with respect to the total amount of the composition. When the content of the carboxyl group-containing resin is less than the above-described range, for example, the strength of the resulting coating film may be reduced; therefore, such a content is not preferred. Meanwhile, when the content is higher than the above-described range, the viscosity of the composition may be increased and the coating properties and the like may be deteriorated; therefore, such a content is not preferred.

The carboxyl group-containing resin is not restricted to those enumerated in the above, and the above-described carboxyl group-containing resins may be used individually, or two or more thereof may be used in combination. In particular, among the above-described carboxyl group-containing resins, those having an aromatic ring are preferred since they have a high refractive index and excellent resolution, and those having a novolac structure are more preferred since they not only have a high resolution but also are excellent in PCT and cracking resistance. Thereamong, the carboxyl group-containing photosensitive resins (1) and (2) are preferred since they can yield a solder resist having satisfactory properties such as PCT resistance, as well as excellent resolution.

### [(B) Acylphosphine Oxide-Based Photopolymerization Initiator]

The above-described (B) acylphosphine oxide-based photopolymerization initiator may be any acylphosphine oxide-based photopolymerization initiator which is known as a photopolymerization initiator or photo radical initiator. Specific examples of such acylphosphine oxide-based photopolymerization initiator include (2,6-dimethoxybenzoyl)-2,4,4-pentylphosphine oxide, 2,4,6-trimethylbenzoyl diphenylphosphine oxide, bis(2,4,6-trimethylbenzoyl)-phenylphosphine oxide, bis(2,6-dimethoxybenzoyl)-2,4,4-trimethyl-pentylphosphine oxide, 2-methylbenzoyldiphenylphosphine oxide, 2,4,6-trimethylbenzoylphenyl phosphinic acid methyl ester, bis(2,6-dimethoxybenzoyl)phenylphosphine oxide and ethyl-2,4,6-trimethylbenzoylphenyl phosphinate. Examples of commercially available acylphosphine oxide-based photopolymerization initiator include LUCIRIN TPO, LUCIRIN TPO-L, LR8953X, IRGACURE 819 and IRGACURE 1700, all of which are manufactured by BASF Japan Ltd.

As the above-described (B) acylphosphine oxide-based photopolymerization initiator, one which has a group represented by the following Formula (I) is preferred:

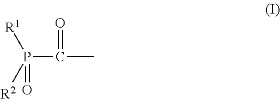

(wherein, R¹ and R² each independently represent a halogen atom, a linear or branched alkyl group having 1 to 6 carbon atoms, a linear or branched alkoxy group having 1 to 6 carbon atoms, a cycloalkyl group having 5 to 20 carbon atoms, an aryl group having 6 to 20 carbon atoms which is optionally substituted with at least one of alkyl groups and alkoxy groups, or an arylcarbonyl group having 7 to 20 carbon atoms which is optionally substituted with at least one of alkyl groups and alkoxy groups).

Examples of the above-described halogen atom include fluorine, chlorine, bromine and iodine. Examples of the above-described linear or branched alkyl group having 1 to 6 carbon atoms include methyl group, ethyl group, propyl group, isopropyl group, butyl group, t-butyl group, pentyl group and hexyl group. Examples of the above-described linear or branched alkoxy group having 1 to 6 carbon atoms include methoxy group, ethoxy group, propoxy group, butoxy group, pentyloxy group and hexyloxy group. Examples of the above-described cycloalkyl group having 5 to 20 carbon atoms include cyclopentyl group, cyclohexyl group and these cycloalkyl groups that are substituted with an alkyl group, an alkoxy group or the like. Examples of the above-described aryl group having 6 to 20 carbon atoms which is optionally substituted with at least one of alkyl groups and alkoxy groups include phenyl group, naphthyl group and these aryl groups that are substituted with at least one of alkyl groups and alkoxy groups. The above-described arylcarbonyl group having 7 to 20 carbon atoms which is optionally substituted with at least one of alkyl groups and alkoxy groups is a group represented by A-(C═O)— (wherein, A represents the above-described aryl group which is optionally substituted with at least one of alkyl groups and alkoxy groups), and specific examples thereof include benzyl group and trimethylbenzyl group.

The above-described (B) acylphosphine oxide-based photopolymerization initiator may be used individually, or two or more thereof may be used in combination. In the photocurable resin composition according to the present invention, the content of the above-described (B) acylphosphine oxide-based photopolymerization initiator is preferably 0.5 to 50 parts by mass, more preferably 1 to 30 parts by mass, with respect to 100 parts by mass of the (A) carboxyl group-containing resin.

### [(C) Titanocene-Based Photopolymerization Initiator]

As the (C) titanocene-based photopolymerization initiator, any known photopolymerization initiator which has a titanocene structure and is capable of exhibiting photosensitivity at a light absorption wavelength of 400 to 700 nm may be employed. Specific examples of the titanocene-based photopolymerization initiator include bis(cyclopentadienyl)-bis[2,6-difluoro-3-(2-(1-pil-1-yl)ethyl)phenyl]titanium, bis(cyclopentadienyl)-bis[2,6-difluoro-3-(3-(1-pil-1-yl)propyl)phenyl]titanium, bis(cyclopentadienyl)-bis[2,6-difluoro-3-((1-pil-1-yl)methyl)phenyl]titanium, bis(methylcyclopentadienyl)-bis[2,6-difluoro-3-((1-pil-1-yl)methyl)phenyl]titanium, bis(cyclopentadienyl)-bis[2,6-difluoro-3-((2,5-dimethyl-1-pil-1-yl)methyl)phenyl]titanium, bis(cyclopentadienyl)-bis[2,6-difluoro-3-((2-isopropyl-5-methyl-1-pil-1,6-yl) methyl)phenyl]titanium, bis(cyclopentadienyl)-bis[2,6-difluoro-3-((2-(2-methoxyethyl)-5-methyl-1-pil-1-yl) methyl)phenyl]titanium, bis(cyclopentadienyl)-bis[2,6-difluoro-3-((3-trimethylsilyl-2,5-dimethyl-1-pil-1-yl) methyl)phenyl]titanium, bis(cyclopentadienyl)-bis[2,6-difluoro-3-((2,5-dimethyl-3-(bis(2-methoxyethyl)aminomethyl)-1-pil-1-yl)methyl)phenyl]titanium, bis(cyclopentadienyl)-bis[2,6-difluoro-3-((2,5-bis(morpholinomethyl)-1-pil-1-yl) methyl)phenyl]titanium, bis(cyclopentadienyl)-bis[2,6-difluoro-3-((2,5-dimethyl-3-(1,3-dioxolane-2-yl)-1-pil-1-yl)methyl)phenyl]titanium, bis(cyclopentadienyl)-bis[2,6-difluoro-4-((2,5-dimethyl-1-pil-1-yl)methyl)phenyl]titanium, bis(cyclopentadienyl)-bis[2,6-difluoro-3-methyl-4-(2-(1-pil-1-yl)ethyl)phenyl]titanium, bis(cyclopentadienyl)-bis[2,6-difluoro-3-((2,3,4,5-tetramethyl-1-pil-1-yl)methyl) phenyl]titanium, bis(cyclopentadienyl)-bis[2,3,5,6-tetrafluoro-4-(3-(1-pil-1-yl)propyl)phenyl]titanium, bis(cyclopentadienyl)-bis[2,6-difluoro-3-(2-(1-pil-1-yl)propyl)phenyl]titanium, bis(cyclopentadienyl)-bis[2,6-difluoro-3-(1-methyl-2-(1-pil-1-yl)ethyl)phenyl]titanium, bis(cyclopentadienyl)-bis[2,6-difluoro-3-(3-(2-isoindole-2-yl)propyl)phenyl]titanium, bis(cyclopentadienyl)-bis[2,6-difluoro 3-(2-(4,5,6,7-tetrahydro-isoindole-2-yl)ethyl)phenyl]titanium, bis(cyclopentadienyl)-bis[2,6-difluoro-3-(6-(9-carbazole-9-yl)hexyl)phenyl]titanium, bis(cyclopentadienyl)-bis[2,6-difluoro-3-(3-(2,3,4,5,6,7,8,9-octahydro-1-carbazole-9-yl)propyl)phenyl]titanium, bis(cyclopentadienyl)-bis[2,6-difluoro-3-(3-(4,5,6,7-tetrahydro-2-methyl-1-indole-1-yl)propyl)phenyl]titanium, bis(cyclopentadienyl)-bis[2,6-difluoro-3-((acetylamino)methyl)phenyl]titanium, bis(cyclopentadienyl)-bis[2,6-difluoro-3-(2-(propionylamino)ethyl)phenyl]titanium, bis(cyclopentadienyl)-bis[2,6-difluoro-3-(3-(acetylamino)propyl)phenyl]titanium, bis(cyclopentadienyl)-bis[2,6-difluoro-3-(4-(pivaloylamino)butyl)phenyl]titanium, bis(cyclopentadienyl)-bis[2,6-difluoro-3-(2-(2,2-dimethylpentanoylamino)ethyl) phenyl]titanium, bis(cyclopentadienyl)-bis[2,6-difluoro-3-(3-(benzoylamino)propyl)phenyl]titanium, bis(cyclopentadienyl)-bis[2,6-difluoro-3-((2,2-dimethylpentanoylamino)methyl) phenyl]titanium, bis(cyclopentadienyl)-bis[2,6-difluoro-3-(2-(2,2-dimethyl-3-chloropropanoylamino) ethyl)phenyl]titanium, bis(cyclopentadienyl)-bis[2,6-difluoro-3-((2,2-dimethyl-3-ethoxypropanoylamino) methyl)phenyl]titanium, bis(cyclopentadienyl)-bis[2,6-difluoro-3-(2-(lauroylamino)ethyl)phenyl]titanium, bis(cyclopentadienyl)-bis[2,6-difluoro-3-(2-(N-allylmethylsulfonylamino)ethyl) phenyl]titanium, bis(cyclopentadienyl)-bis[2,6-difluoro-3-(3-(N-isobutylphenylsulfonylamino)propyl) phenyl]titanium, bis(cyclopentadienyl)-bis[2,6-difluoro-3-((methylsulfonylamino)methyl)phenyl]titanium, bis(cyclopentadienyl)-bis[2,6-difluoro-3-(3-(ethylsulfonylamino)propyl)phenyl]titanium, bis(cyclopentadienyl)-bis[2,6-difluoro-3-(2-(butylsulfonylamino)ethyl)phenyl]titanium, bis(cyclopentadienyl)-bis[2,6-difluoro-3-(4-(trisulfonylamino)propyl)phenyl]titanium and bis(η⁵-2,4-cyclopentadiene-1-yl)-bis(2,6-difluoro-3-(1H-pyrrole-1-yl)phenyl) titanium. These titanocene-based photopolymerization initiators may be used individually, or two or more thereof may be used in combination. Examples of commercially available titanocene-based photopolymerization initiator include IRGACURE 784 manufactured by BASF Japan Ltd.

Further, as the (C) titanocene-based photopolymerization initiator, a compound represented by the following Formula (II) is preferred and a compound represented by the following Formula (III) is more preferred.

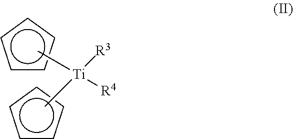

(wherein, R³ and R⁴ each independently represent an aryl group having 6 to 20 carbon atoms which is optionally substituted with at least one selected from halogen atoms, alkyl groups, alkoxy groups, alkylcarbonyl groups, alkoxyalkylcarbonyl groups, aryl groups and heterocyclic groups.)

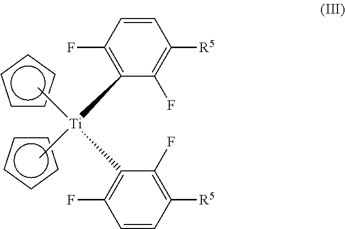

(wherein, R⁵ and R⁶ each independently represent a linear or branched alkylcarbonyl group having 2 to 14 carbon atoms, an alkoxyalkylcarbonyl group having 3 to 14 carbon atoms or a 5- or 6-membered heterocyclic group having a nitrogen atom, a sulfur atom or an oxygen atom as the hetero atom.)

Examples of the halogen atom, alkyl group, alkoxy group and aryl group include the same ones as those described in the above. The above-described alkylcarbonyl group is a group in which the above-described alkyl group is bound to a carbonyl group. The above-described alkoxyalkylcarbonyl group is a group in which an alkyl group substituted with an alkoxy group is bound to a carbonyl group. Examples of the 5- or 6-membered heterocyclic group having a nitrogen atom, a sulfur atom or an oxygen atom as the hetero atom include pyrrolidine, tetrahydrofuran, tetrahydrothiophene, pyrrole, furan, thiophene, piperidine, tetrahydropyran and pyridine.

As the above-described (C) titanocene-based photopolymerization initiator, a compound represented by the following formula is particularly preferred.

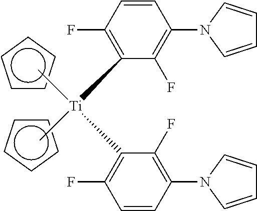

The above-described titanocene-based photopolymerization initiators may be used individually, or two or more thereof may be used in combination. In the photocurable resin composition according to the present invention, the content of the (C) titanocene-based photopolymerization initiator is preferably 0.01 to 10 parts by mass, more preferably 0.01 to 8 parts by mass, with respect to 100 parts by mass of the (A) carboxyl group-containing resin.

Further, the ratio (B):(C) is preferably 1:0.01 to 1:1, more preferably 1:0.01 to 1:0.5.

### [(D) Photosensitive Monomer]

The (D) photosensitive monomer is a compound having an ethylenically unsaturated group in the molecule and is used for adjusting the viscosity of the photocurable resin composition, facilitating the photocurability and improving the developing property. As such a compound, commonly used and known polyester (meth)acrylate, polyether (meth)acrylate, urethane (meth)acrylate, carbonate (meth)acrylate, epoxy (meth)acrylate or urethane (meth)acrylate may be employed, and specific examples thereof include hydroxyalkyl acrylates such as 2-hydroxyethylacrylate and 2-hydroxypropylacrylate; glycol diacrylates such as ethylene glycol, methoxytetraethylene glycol, polyethylene glycol and propylene glycol; acrylamides such as N,N-dimethylacrylamide, N-methylolacrylamide and N,N-dimethylaminopropylacrylamide; aminoalkyl acrylates such as N,N-dimethylaminoethyl acrylate and N,N-dimethylaminopropyl acrylate; polyvalent acrylates of polyhydric alcohols (e.g. hexanediol, trimethylolpropane, pentaerythritol, dipentaerythritol and tris-hydroxyethyl isocyanurate) and ethylene oxide adducts, propylene oxide adducts or ε-caprolactone adducts of these polyhydric alcohols; polyvalent acrylates such as phenoxyacrylate, bisphenol A diacrylate and ethylene oxide adducts or propylene oxide adducts of these phenols; polyvalent acrylates of glycidyl ethers such as glycerin diglycidyl ether, glycerin triglycidyl ether, trimethylolpropane triglycidyl ether and triglycidyl isocyanate. In addition to the above, examples also include acrylates and melamine acrylates that are obtained by direct acrylation or diisocyanate-mediated urethane acrylation of a polyol such as polyether polyol, polycarbonate diol, hydroxyl group-terminated polybutadiene or polyester polyol; and methacrylates corresponding to the above-described acrylates.

Further, as the photosensitive monomer, for example, an epoxy acrylate resin which is obtained by allowing a multifunctional epoxy resin such as a cresol novolac-type epoxy resin to react with acrylic acid or an epoxy urethane acrylate compound which is obtained by allowing the hydroxyl group of the above-described epoxy acrylate resin to react with a hydroxyacrylate such as pentaerythritol triacrylate and a half urethane compound of diisocyanate such as isophorone diisocyanate may also be employed. These epoxy acrylate-based resins are capable of improving the photocurability of the photocuring resin composition without impairing the dryness to touch.

The above-described compounds having an ethylenically unsaturated group in the molecule may be used individually, or two or more thereof may be used in combination. In particular, from the standpoints of photoreactivity and resolution, a compound having 4 to 6 ethylenically unsaturated groups in one molecule is preferred. Further, a compound having two ethylenically unsaturated groups in one molecule is also preferably used since it lowers the linear thermal expansion coefficient of the resulting cured product and reduces the occurrence of peeling during PCT.

The content of the above-described compound having an ethylenically unsaturated group(s) in the molecule is preferably 5 to 100 parts by mass with respect to 100 parts by mass of the above-described (A) carboxyl group-containing resin. When the content is less than 5 parts by mass, the photocurability of the photocuring resin composition is impaired, so that it may become difficult to form a pattern by development with an alkali after irradiation with an active energy beam. Meanwhile, when the content is higher than 100 parts by mass, the solubility of the photocuring resin composition to a dilute aqueous alkali solution may be reduced, making the resulting coating film fragile. The content of the above-described compound having an ethylenically unsaturated group(s) in the molecule is more preferably 1 to 70 parts by mass.

### [(E) Polymerization Inhibitor]

In order to improve the storage stability, it is preferred that (E) a polymerization inhibitor be added to the photocurable resin composition according to the present invention. As the (E) polymerization inhibitor, a commonly used and known (thermal) polymerization inhibitor can be employed. Examples of the (E) polymerization inhibitor include phenothiazines, hydroquinones, N-phenylnaphthylamines, chloranils, pyrogallols, benzoquinones, t-butylcatechols, hydroquinones, methylhydroquinones, hydroquinone monomethyl ethers, catechols, pyrogallols, naphthoquinones and naphthoquinone derivatives such as 4-methoxy-1-naphthol and 2-hydroxy-1,4-naphthoquinone. Thereamong, the (E) polymerization inhibitor is preferably a naphthoquinone or a naphthoquinone derivative.

The above-described polymerization inhibitors may be used individually, or two or more thereof may be used in combination. In the photocurable resin composition according to the present invention, the content of the polymerization inhibitor(s) is preferably 0.01 to 5 parts by mass, more preferably 0.05 to 3 parts by mass, with respect to 100 parts by mass of the (A) carboxyl group-containing resin.

### (Other Photopolymerization Initiator)

The photocurable resin composition according to the present invention may also contain a photopolymerization initiator other than the above-described acrylphosphine oxide-based photopolymerization initiator and titanocene-based photopolymerization initiator in such an amount that the effects of the present invention are not adversely affected. Examples of such photopolymerization initiator include oxime ester-based photopolymerization initiators having an oxime ester group, alkylphenone-based photopolymerization initiators and α-aminoacetophenone-based photopolymerization initiators.

Particularly, the above-described oxime ester-based photopolymerization initiators are preferred since they require only a small amount for inhibiting generation of outgas and exhibiting an effect of imparting PCT resistance and cracking resistance.

Examples of commercially available oxime ester-based photopolymerization initiator include CGI-325, IRGACURE OXE01 and IRGACURE OXE02, which are manufactured by BASF Japan, Ltd.; and N-1919 and NCl-831, which are manufactured by ADEKA Corporation. Further, a photopolymerization initiator having two oxime ester groups in the molecule can also be suitably used, and specific examples thereof include those oxime ester compounds having a carbazole structure represented by the following formula:

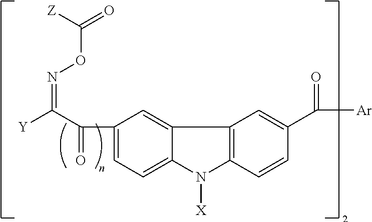

(wherein, X represents a hydrogen atom, an alkyl group having 1 to 17 carbon atoms, an alkoxy group having 1 to 8 carbon atoms, a phenyl group, a phenyl group (which is substituted with an alkyl group having 1 to 17 carbon atoms, an alkoxy group having 1 to 8 carbon atoms, an amino group, or an alkylamino or dialkylamino group having containing an alkyl group having 1 to 8 carbon atoms), a naphthyl group (which is substituted with an alkyl group having 1 to 17 carbon atoms, an alkoxy group having 1 to 8 carbon atoms, an amino group, or an alkylamino or dialkylamino group having containing an alkyl group having 1 to 8 carbon atoms); Y and Z each independently represent a hydrogen atom, an alkyl group having 1 to 17 carbon atoms, an alkoxy group having 1 to 8 carbon atoms, a halogen group, a phenyl group, a phenyl group (which is substituted with an alkyl group having 1 to 17 carbon atoms, an alkoxy group having 1 to 8 carbon atoms, an amino group, or an alkylamino or dialkylamino group having containing an alkyl group having 1 to 8 carbon atoms), a naphthyl group (which is substituted with an alkyl group having 1 to 17 carbon atoms, an alkoxy group having 1 to 8 carbon atoms, an amino group, or an alkylamino or dialkylamino group having containing an alkyl group having 1 to 8 carbon atoms), an anthryl group, a pyridyl group, a benzofuryl group or a benzothienyl group; Ar represents a bond, an alkylene having 1 to 10 carbon atoms, a vinylene, a phenylene, a biphenylene, a pyridylene, a naphthylene, a thiophene, an anthrylene, a thienylene, a furylene, 2,5-pyrrole-diyl, 4,4′-stilbene-diyl or 4,2′-styrene-diyl; and n is an integer of 0 or 1).

Particularly, in the above-described formula, it is preferred that X and Y be each a methyl group or an ethyl group; Z be methyl or phenyl; n be 0; and Ar be a bond, a phenylene, a naphthylene, a thiophene or a thienylene.

Further, examples of preferred carbazole oxime ester compound include those compounds that are represented by the following formula:

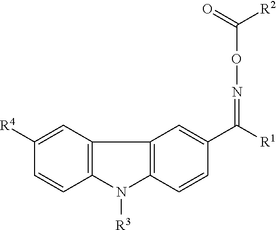

(wherein, R¹ represents an alkyl group having 1 to 4 carbon atoms or a phenyl group which is optionally substituted with a nitro group, a halogen atom or an alkyl group having 1 to 4 carbon atoms;

R² represents an alkyl group having 1 to 4 carbon atoms, an alkoxy group having 1 to 4 carbon atoms or a phenyl group which is optionally substituted with an alkyl or alkoxy group having 1 to 4 carbon atoms;

R³ is optionally linked via an oxygen atom or a sulfur atom and represents an alkyl group having 1 to 20 carbon atoms which is optionally substituted with a phenyl group or a benzyl group which is optionally substituted with an alkoxy group having 1 to 4 carbon atoms;

R⁴ represents a nitro group or an acyl group represented by X—C(═O)—; and

X represents an aryl group which is optionally substituted with an alkyl group having 1 to 4 carbon atoms, a thienyl group, a morpholino group, a thiophenyl group or a structure represented by the following formula).

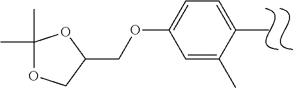

In addition to the above, examples of preferred carbazole oxime ester compound include those described in Japanese Unexamined Patent Application Publication Nos. 2004-359639, 2005-097141, 2005-220097, 2006-160634, 2008-094770 and 2011-80036 and Japanese Translated PCT Patent Application Laid-open Nos. 2008-509967 and 2009-040762.

Examples of commercially available alkylphenone-based photopolymerization initiator include α-hydroxyalkylphenone-type photopolymerization initiators such as IRGACURE 184, DAROCUR 1173, IRGACURE 2959 and IRGACURE 127, all of which are manufactured by BASF Japan Ltd.

Specific examples of the α-aminoacetophenone-based photopolymerization initiator include 2-methyl-1-[4-(methylthio)phenyl]-2-morpholinopropanone-1, 2-benzyl-2-dimethylamino-1-(4-morpholinophenyl)-butane-1-one, 2-(dimethylamino)-2-[(4-methylphenyl)methyl]-1-[4-(4-morpholinyl)phenyl]-1-buta none and N,N-dimethylaminoacetophenone. Examples of commercially available α-aminoacetophenone-based photopolymerization initiator include IRGACURE 907, IRGACURE 369 and IRGACURE 379, all of which are manufactured by BASF Japan Ltd.

Further, as the photopolymerization initiator, IRGACURE 389 manufactured by BASF Japan Ltd. can also be suitably employed.

### (Photoinitiator Aid, Sensitizer)

In addition to the above-described photopolymerization initiator, the photocurable resin composition according to the present invention may also contain a photoinitiator aid and/or a sensitizer in such an amount that the effects of the present invention are not adversely affected. Examples of photoinitiator aid and sensitizer that can be suitably used include benzoin compounds, acetophenone compounds, anthraquinone compounds, thioxanthone compounds, ketal compounds, benzophenone compounds, tertiary amine compounds and xanthone compound.

Specific examples of the benzoin compounds include benzoin, benzoin methyl ether, benzoin ethyl ether and benzoin isopropyl ether.

Specific examples of the acetophenone compounds include acetophenone, 2,2-dimethoxy-2-phenyl acetophenone, 2,2-diethoxy-2-phenyl acetophenone and 1,1-dichloroacetophenone.

Specific examples of the anthraquinone compounds include 2-methylanthraquinone, 2-ethylanthraquinone, 2-t-butylanthraquinone and 1-chloroanthraquinone.

Specific examples of the thioxanthone compounds include 2,4-dimethylthioxanthone, 2,4-diethylthioxanthone, 2-chlorothioxanthone and 2,4-diisopropylthioxanthone.

Specific examples of the ketal compounds include acetophenone dimethyl ketal and benzyldimethyl ketal.

Specific examples of the benzophenone compounds include benzophenone, 4-benzoyldiphenylsulfide, 4-benzoyl-4′-methyldiphenylsulfide, 4-benzoyl-4′-ethyldiphenylsulfide and 4-benzoyl-4′-propyldiphenylsulfide.

Specific examples of the tertiary amine compounds include ethanolamine compounds and compounds having a dialkylaminobenzene structure, and examples of commercially available products thereof include dialkylaminobenzophenones such as 4,4′-dimethylaminobenzophenone (NISSO CURE MABP manufactured by Nippon Soda Co., Ltd.) and 4,4′-diethylaminobenzophenone (EAB manufactured by Hodogaya Chemical Co., Ltd.); dialkylamino group-containing coumarin compounds such as 7-(diethylamino)-4-methyl-2H-1-benzopyran-2-one (7-(diethylamino)-4-methylcoumarin); ethyl-4-dimethylaminobenzoate (KAYACURE EPA manufactured by Nippon Kayaku Co., Ltd.); ethyl-2-dimethylaminobenzoate (QUANTACURE DMB manufactured by International BioSynthetics Inc.); (n-butoxy)ethyl-4-dimethylaminobenzoate (QUANTACURE BEA manufactured by International BioSynthetics Inc.); isoamylethyl-p-dimethylaminobenzoate (KAYACURE DMBI manufactured by Nippon Kayaku Co., Ltd.); 2-ethylhexyl-4-dimethylaminobenzoate (ESOLOL 507 manufactured by Van Dyk GmbH); and 4,4′-diethylaminobenzophenone (EAB manufactured by Hodogaya Chemical Co., Ltd.).

Among the above-described compounds, thioxanthone compounds and tertiary amine compounds are preferred. In particular, from the standpoint of the curability of the resulting coating film in a deep portion, it is preferred that the photocurable resin composition according to the present invention contain a thioxanthone compound, for example, 2,4-dimethylthioxanthone, 2,4-diethylthioxanthone, 2-chlorothioxanthone or 2,4-diisopropylthioxanthone.

The content of such thioxanthone compound is preferably not higher than 20 parts by mass with respect to 100 parts by mass of the above-described carboxyl group-containing resin. When the content of the thioxanthone compound is higher than 20 parts by mass, the curability of a thick film is deteriorated, leading to an increase in the production cost. The content of the thioxanthone compound is more preferably not higher than 10 parts by mass.

Further, as the tertiary amine compound, those compounds having a dialkylaminobenzene structure are preferred. Particularly preferred thereamong are dialkylaminobenzophenone compounds and dialkylamino group-containing coumarin compounds and ketocumarins that have a maximum absorption wavelength in the range of 350 to 450 nm.

As a dialkylaminobenzophenone compound, 4,4′-diethylaminobenzophenone is preferred because of its low toxicity. Since a dialkylamino group-containing coumarin compound has a maximum absorption wavelength in the ultraviolet region of 350 to 410 nm, it causes little coloration, so that it becomes possible to provide not only a colorless and transparent photocurable composition, but also a colored solder resist which reflects the color of a coloring pigment itself by using a coloring pigment. In particular, 7-(diethylamino)-4-methyl-2H-1-benzopyran-2-one is preferred since it exhibits excellent sensitization effect to a laser beam having a wavelength of 400 to 410 nm.

The content of such tertiary amine compound is preferably 0.1 to 20 parts by mass with respect to 100 parts by mass of the above-described (A) carboxyl group-containing resin. When the content of the tertiary amine compound is less than 0.1 parts by mass, sufficient sensitization effect tends not to be attained. Meanwhile, when the content is higher than 20 parts by mass, light absorption by the tertiary amine compound on the surface of a dried solder resist becomes intense, so that the curability of the resulting coating film in a deep portion tends to be impaired. The content of the tertiary amine compound is more preferably 0.1 to 10 parts by mass.

These photopolymerization initiators, photoinitiator aids and sensitizers may be used individually, or two or more thereof may be used in combination.

It is preferred that the total amount of the photopolymerization initiator(s), photoinitiator aid(s) and sensitizer(s) be not greater than 35 parts by mass with respect to 100 parts by mass of the above-described (A) carboxyl group-containing resin. When the amount exceeds 35 parts by mass, the light absorption by these components tends to deteriorate the curability of the resulting coating film in a deep portion.

To the photocurable resin composition according to the present invention, a thermosetting component may be added. By adding a thermosetting component, the heat resistance is expected to be improved. Examples of such thermosetting component that can be used in the present invention include amino resins such as melamine resins, benzoguanamine resins, melamine derivatives and benzoguanamine derivatives; blocked isocyanate compounds; cyclocarbonate compounds; multifunctional epoxy compounds; multifunctional oxetane compounds; and known thermosetting resins such as episulfide resins, bismaleimides and carbodiimide resins. Thereamong, a thermosetting component having at least either of a cyclic ether group and a cyclic thioether group (hereinafter, simply referred to as “cyclic (thio)ether group”) in a plural number in one molecule is particularly preferred.

The above-described thermosetting component having a plurality of cyclic (thio)ether groups in the molecule is a compound having one or more of 3-, 4- and 5-membered cyclic (thio)ether groups in the molecule, and examples thereof include compounds having a plurality of epoxy groups in the molecule, that is, multifunctional epoxy compounds; compound having a plurality of oxetanyl groups in the molecule, that is, multifunctional oxetane compounds; and compounds having a plurality of thioether groups in the molecule, that is, episulfide resins.

Examples of the above-described multifunctional epoxy compounds include epoxidized vegetable oils such as ADK CIZER O-130P, ADK CIZER O-180A, ADK CIZER D-32 and ADK CIZER D-55, which are manufactured by ADEKA Corporation; bisphenol A-type epoxy resins such as jER828, jER834, jER1001 and jER1004, which are manufactured by Mitsubishi Chemical Corporation, EHPE3150 manufactured by Daicel Chemical Industries, Ltd., EPICLON 840, EPICLON 850, EPICLON 1050 and EPICLON 2055, which are manufactured by DIC Corporation, EPOTOHTO YD-011, YD-013, YD-127 and YD-128, which are manufactured by Tohto Kasei Co., Ltd., D.E.R.317, D.E.R.331, D.E.R.661 and D.E.R.664, which are manufactured by The Dow Chemical Company, SUMI-EPDXY ESA-011, ESA-014, ELA-115 and ELA-128, which are manufactured by Sumitomo Chemical Co., Ltd., and A.E.R.330, A.E.R.331, A.E.R.661 and A.E.R.664, which are manufactured by Asahi Chemical Industry Co., Ltd. (all of the above are trade names); hydroquinone-type epoxy resin YDC-1312, bisphenol-type epoxy resin YSLV-80XY and thioether-type epoxy resin YSLV-120TE (all of which are manufactured by Tohto Kasei Co., Ltd.); brominated epoxy resins such as jERYL 903 manufactured by Mitsubishi Chemical Corporation, EPICLON 152 and EPICLON 165, which are manufactured by DIC Corporation, EPOTOHTO YDB-400 and YDB-500, which are manufactured by Tohto Kasei Co., Ltd., D.E.R.542 manufactured by The Dow Chemical Company, SUMI-EPDXY ESB-400 and ESB-700, which are manufactured by Sumitomo Chemical Co., Ltd., and A.E.R.711 and A.E.R.714, which are manufactured by Asahi Chemical Industry Co., Ltd. (all of the above are trade names); novolac-type epoxy resins such as jER152 and jER154, which are manufactured by Mitsubishi Chemical Corporation, D.E.N.431 and D.E.N.438, which are manufactured by The Dow Chemical Company, EPICLON N-730, EPICLON N-770 and EPICLON N-865, which are manufactured by DIC Corporation, EPOTOHTO YDCN-701 and YDCN-704, which are manufactured by Tohto Kasei Co., Ltd., EPPN-201, EOCN-1025, EOCN-1020, EOCN-104S and RE-306, which are manufactured by Nippon Kayaku Co., Ltd., SUMI-EPDXY ESCN-195X and ESCN-220, which are manufactured by Sumitomo Chemical Co., Ltd., and A.E.R.ECN-235 and ECN-299, which are manufactured by Asahi Chemical Industry Co., Ltd., (all of the above are trade names); biphenol novolac-type epoxy resins such as NC-3000 and NC-3100, which are manufactured by Nippon Kayaku Co., Ltd.; bisphenol F-type epoxy resins such as EPICLON 830 manufactured by DIC Corporation, jER807 manufactured by Mitsubishi Chemical Corporation, and EPOTOHTO YDF-170, YDF-175 and YDF-2004 which are manufactured by Tohto Kasei Co., Ltd. (all of the above are trade names); hydrogenated bisphenol A-type epoxy resins such as EPOTOHTO ST-2004, ST-2007 and ST-3000 (trade names) which are manufactured by Tohto Kasei Co., Ltd.; glycidyl amine-type epoxy resins such as jER604 manufactured by Mitsubishi Chemical Corporation, EPOTOHTO YH-434 manufactured by Tohto Kasei Co., Ltd. and SUMI-EPDXY ELM-120 manufactured by Sumitomo Chemical Co., Ltd. (all of the above are trade names); hydantoin-type epoxy resins; alicyclic epoxy resins such as CELLOXIDE 2021 (trade name) manufactured by Daicel Corporation; trihydroxyphenyl methane-type epoxy resins such as YL-933 manufactured by Mitsubishi Chemical Corporation and T.E.N., EPPN-501 and EPPN-502, which are manufactured by The Dow Chemical Company (all of the above are trade names); bixylenol-type or biphenol-type epoxy resins and mixtures thereof, such as YL-6056, YX-4000 and YL-6121 (all of which are trade names) manufactured by Mitsubishi Chemical Corporation; bisphenol S-type epoxy resins such as EBPS-200 manufactured by Nippon Kayaku Co., Ltd., EPX-30 manufactured by ADEKA Corporation and EXA-1514 (trade name) manufactured by DIC Corporation; bisphenol A novolac-type epoxy resins such as jER157S (trade name) manufactured by Mitsubishi Chemical Corporation; tetraphenylolethane-type epoxy resins such as jERYL-931 (trade name) manufactured by Mitsubishi Chemical Corporation; heterocyclic epoxy resins such as TEPIC (trade name) manufactured by Nissan Chemical Industries, Ltd.; diglycidyl phthalate resins such as BLEMMER DGT manufactured by NOF Corporation; tetraglycidyl xylenoylethane resins such as ZX-1063 manufactured by Tohto Kasei Co., Ltd.; naphthalene group-containing epoxy resins such as ESN-190 and ESN-360, which are manufactured by Nippon Steel Chemical Co., Ltd., and HP-4032, EXA-4750 and EXA-4700, which are manufactured by DIC Corporation; epoxy resins having a dicyclopentadiene skeleton, such as HP-7200 and HP-7200H manufactured by DIC Corporation; glycidyl methacrylate copolymer-based epoxy resins such as CP-50S and CP-50M manufactured by NOF Corporation; cyclohexylmaleimide-glycidyl methacrylate copolymer epoxy resins; epoxy-modified polybutadiene rubber derivatives (for example, P13-3600 manufactured by Daicel Chemical Industries, Ltd.); and CTBN-modified epoxy resins (for example, YR-102 and YR-450 manufactured by Tohto Kasei Co., Ltd.). However, the multifunctional epoxy compound is not restricted to these resins. These epoxy resins may be used individually, or two or more thereof may be used in combination. Thereamong, particularly preferred are novolac-type epoxy resins, bixylenol-type epoxy resins, biphenol-type epoxy resins, biphenol novolac-type epoxy resins, naphthalene-type epoxy resins, and mixtures thereof.

Examples of the multifunctional oxetane compounds include multifunctional oxetanes such as bis[(3-methyl-3-oxcetanylmethoxy)methyl]ether, bis[(3-ethyl-3-oxcetanylmethoxy)methyl]ether, 1,4-bis[(3-methyl-3-oxcetanylmethoxy)methyl]benzene, 1,4-bis[(3-ethyl-3-oxcetanylmethoxy)methyl]benzene, (3-methyl-3-oxcetanyl)methyl acrylate, (3-ethyl-3-oxcetanyemethyl acrylate, (3-methyl-3-oxcetanyl)methyl methacrylate, (3-ethyl-3-oxcetanyl)methyl methacrylate, and oligomers and copolymers thereof; and etherification products of an oxetane alcohol and a resin having a hydroxyl group, such as a novolac resin, a poly(p-hydroxystyrene), a cardo-type bisphenol, a calixarene, a calix resorcin arene or a silsesquioxane. Other examples include copolymers of an unsaturated monomer having an oxetane ring and an alkyl(meth)acrylate.

Examples of the compounds having a plurality of cyclic thioether groups in the molecule include bisphenol A-type episulfide resin YL7000 manufactured by Mitsubishi Chemical Corporation. Further, for example, an episulfide resin prepared by the same synthesis method except that an oxygen atom of an epoxy group of a novolac-type epoxy resin is substituted with a sulfur atom can also be used.

The content of such thermosetting component having a plurality of cyclic (thio)ether groups in the molecule is preferably 0.6 to 2.5 equivalents with respect to 1 equivalent of carboxyl group in the above-described (A) carboxyl group-containing resin. When the content is less than 0.6 equivalent, carboxyl groups remain in the resulting cured product, causing deterioration in the heat resistance, alkali resistance, electric insulation properties and the like. Meanwhile, when the content is higher than 2.5 equivalents, cyclic (thio)ether groups having a low molecular weight remain in the resulting dry coating film, causing deterioration in the coating film strength and the like. The content of the thermosetting component having a plurality of cyclic (thio)ether groups in the molecule is more preferably 0.8 to 2.0 equivalents.

Further, examples of other thermosetting component include amino resins such as melamine derivatives and benzoguanamine derivatives, for example, methylol melamine compounds, methylol benzoguanamine compounds, methylol glycoluril compounds and methylol urea compounds. Moreover, alkoxymethylated melamine compounds, alkoxymethylated benzoguanamine compounds, alkoxymethylated glycoluril compounds and alkoxymethylated urea compounds are obtained by converting the methylol group of the respective methylol melamine compounds, methylol benzoguanamine compounds, methylol glycoluril compounds and methylol urea compounds into an alkoxymethyl group. The type of this alkoxymethyl group is not particularly restricted and examples thereof include methoxymethyl group, ethoxymethyl group, propoxymethyl group and butoxymethyl group. In particular, a melamine derivative having a formalin concentration of not higher than 0.2%, which is not harmful to human body and environment, is preferred.

Examples of commercially available products of the above-described thermosetting components include CYMEL 300, 301, 303, 370, 325, 327, 701, 266, 267, 238, 1141, 272, 202, 1156, 1158, 1123, 1170, 1174, UFR65 and 300 (all of which are manufactured by Mitsui Cyanamid Co., Ltd.); and NIKALAC Mx-750, Mx-032, Mx-270, Mx-280, Mx-290, Mx-706, Mx-708, Mx-40, Mx-31, Ms-11, Mw-30, Mw-30HM, Mw-390, Mw-100LM and Mw-750LM (all of which are manufactured by Sanwa Chemical Co., Ltd.). These thermosetting components may be used individually, or two or more thereof may be used in combination.

In the photocurable resin composition according to the present invention, a compound having a plurality of isocyanate groups or blocked isocyanate groups in one molecule may also be blended. Examples thereof include polyisocyanate compounds and blocked isocyanate compounds. Here, the term “blocked isocyanate group” refers to a group in which isocyanate group is protected and thus temporarily inactivated by a reaction with a blocking agent. When a blocked isocyanate compound is heated to a prescribed temperature, the blocking agent is dissociated to yield an isocyanate group. It was confirmed that the curability of the photocurable resin composition and the toughness of the resulting cured product are improved by adding the above-described polyisocyanate compound or blocked isocyanate compound.

As such polyisocyanate compound, for example, an aromatic polyisocyanate, an aliphatic polyisocyanate or an alicyclic polyisocyanate may be employed.

Specific examples of the aromatic polyisocyanate include 4,4′-diphenylmethane diisocyanate, 2,4-tolylene diisocyanate, 2,6-tolylene diisocyanate, naphthalene-1,5-diisocyanate, o-xylylene diisocyanate, m-xylylene diisocyanate and 2,4-tolylene dimer.

Specific examples of the aliphatic polyisocyanate include tetramethylene diisocyanate, hexamethylene diisocyanate, methylene diisocyanate, trimethylhexamethylene diisocyanate, 4,4-methylenebis(cyclohexylisocyanate) and isophorone diisocyanate.

Specific examples of the alicyclic polyisocyanate include bicycloheptane triisocyanate, as well as adducts, biurets and isocyanurates of the above-described isocyanate compounds.

As the blocked isocyanate compound, a product of an addition reaction between an isocyanate compound and an isocyanate blocking agent is employed. Examples of an isocyanate compound which can react with a blocking agent include the above-described polyisocyanate compounds.

Examples of the isocyanate blocking agent include phenolic blocking agents such as phenol, cresol, xylenol, chlorophenol and ethylphenol; lactam-based blocking agents such as ε-caprolactam, δ-valerolactam, γ-butyrolactam and β-propiolactam; activated methylene-based blocking agents such as ethyl acetoacetate and acetylacetone; alcohol-based blocking agents such as methanol, ethanol, propanol, butanol, amyl alcohol, ethylene glycol monomethyl ether, ethylene glycol monoethyl ether, ethylene glycol monobutyl ether, diethylene glycol monomethyl ether, propylene glycol monomethyl ether, benzyl ether, methyl glycolate, butyl glycolate, diacetone alcohol, methyl lactate and ethyl lactate; oxime-based blocking agents such as formaldehyde oxime, acetaldoxime, acetoxime, methylethyl ketoxime, diacetyl monooxime and cyclohexane oxime; mercaptan-based blocking agents such as butylmercaptan, hexylmercaptan, t-butylmercaptan, thiophenol, methylthiophenol and ethylthiophenol; acid amid-based blocking agents such as acetic acid amide and benzamide; imide-based blocking agents such as succinic acid imide and maleic acid imide; amine-based blocking agents such as xylidine, aniline, butylamine and dibutylamine; imidazole-based blocking agents such as imidazole and 2-ethylimidazole; and imine-based blocking agents such as methyleneimine and propyleneimine.

The blocked isocyanate compound may be a commercially available product and examples thereof include SUMIDUR BL-3175, BL-4165, BL-1100 and BL-1265, DESMODUR TPLS-2957, TPLS-2062, TPLS-2078 and TPLS-2117, and DESMOTHERM 2170 and 2265 (all of which are manufactured by Sumitomo Bayer Urethane Co., Ltd.); CORONATE 2512, CORONATE 2513 and CORONATE 2520 (all of which are manufactured by Nippon Polyurethane Industry Co., Ltd.); B-830, B-815, B-846, B-870, B-874 and B-882 (all of which are manufactured by Mitsui Takeda Chemicals Inc.); and TPA-B80E, 17B-60PX and E402-B80T (all of which are manufactured by Asahi Kasei Chemicals Corporation). It is noted here that SUMIDUR BL-3175 and BL-4265 are produced by using methylethyl oxime as a blocking agent. The above-described compounds having a plurality of isocyanate groups or blocked isocyanate groups in one molecule may be used individually, or two or more thereof may be used in combination.

The content of such compound(s) having a plurality of isocyanate groups or blocked isocyanate groups in one molecule is preferably 1 to 100 parts by mass with respect to 100 parts by mass of the above-described (A) carboxyl group-containing resin. When the content is less than 1 part by mass, a coating film having sufficient toughness may not be obtained. Meanwhile, when the content is higher than 100 parts by mass, the storage stability is deteriorated. The content of the compound(s) having a plurality of isocyanate groups or blocked isocyanate groups in one molecule is more preferably 2 to 70 parts by mass.

### (Thermosetting Catalyst)

In cases where a thermosetting component having a plurality of cyclic (thio)ether groups in the molecule is used, it is preferred that the photocurable resin composition according to the present invention contain a thermosetting catalyst. Examples of the thermosetting catalyst include imidazole derivatives such as imidazole, 2-methylimidazole, 2-ethylimidazole, 2-ethyl-4-methylimidazole, 2-phenylimidazole, 4-phenylimidazole, 1-cyanoethyl-2-phenylimidazole and 1-(2-cyanoethyl)-2-ethyl-4-methylimidazole; amine compounds such as dicyandiamide, benzyldimethylamine, 4-(dimethylamino)-N,N-dimethylbenzylamine, 4-methoxy-N,N-dimethylbenzylamine and 4-methyl-N,N-dimethylbenzylamine; hydrazine compounds such as adipic acid dihydrazide and sebacic acid dihydrazide; and phosphorus compounds such as triphenylphosphine. Further, examples of commercially available thermosetting catalyst include 2MZ-A, 2MZ-OK, 2PHZ, 2P4BHZ and 2P4 MHZ (all of which are imidazole-based compounds; trade names), which are manufactured by Shikoku Chemicals Corporation; and U-CAT (registered trademark) 3503N and U-CAT 3502T (both of which are blocked isocyanate compounds of dimethylamine; trade names) and DBU, DBN, U-CATSA102 and U-CAT5002 (all of which are a bicyclic amidine compound or a salt thereof), which are manufactured by San-Apro Ltd. The thermosetting catalyst is not particularly restricted to these catalysts and it may be a thermosetting catalyst of an epoxy resin or an oxetane compound, or any compound which facilitates the reaction of at least either of an epoxy group and an oxetanyl group with a carboxyl group. These thermosetting catalysts may be used individually, or two or more thereof may be used in combination. Further, a s-triazine derivative, such as guanamine, acetoguanamine, benzoguanamine, melamine, 2,4-diamino-6-methacryloyloxyethyl-s-triazine, 2-vinyl-2,4-diamino-s-triazine, 2-vinyl-4,6-diamino-s-triazine-isocyanuric acid adduct or 2,4-diamino-6-methacryloyloxyethyl-s-triazine-isocyanuric acid adduct, may also be used. Preferably, such compound which also functions as an adhesion-imparting agent is used in combination with a thermosetting catalyst.

The content of the thermosetting catalyst(s) is sufficient at an ordinary quantitative ratio and, for example, it is preferably 0.1 to 20 parts by mass, more preferably 0.5 to 15.0 parts by mass, with respect to 100 parts by mass of the above-described (A) carboxyl group-containing resin or the thermosetting component having a plurality of cyclic (thio)ether groups in the molecule.

### (Inorganic Filler)

It is preferred that the photocurable resin composition according to the present invention contain an inorganic filler. The inorganic filler is used for inhibiting shrinkage on curing of a cured product of the photocurable resin composition and improving its characteristics such as adhesion and hardness. Examples of the inorganic filler include barium sulfate, barium titanate, amorphous silica, crystalline silica, Neuburg siliceous earth, molten silica, spherical silica, talc, clay, magnesium carbonate, calcium carbonate, aluminum oxide, aluminum hydroxide, silicon nitride and aluminum nitride.

Further, it is preferred that the photocurable resin composition according to the present invention also contain a filler whose refractive index is in the range of 1.50 to 1.65. In particular, this filler whose refractive index is in the range of 1.50 to 1.65 preferably contains at least one of Ba, Mg and Al.

It is preferred that the above-described inorganic filler have an average particle size of not larger than 5 μm. The content thereof is preferably not higher than 75% by mass, more preferably 0.1 to 60% by mass, based on the total amount of solids contained in the above-described photocurable resin composition. When the content of the inorganic filler is higher than 75% by mass, the viscosity of the composition may be increased to impair the coating properties and the resulting cured product of the photocurable resin composition may become fragile.

### (Elastomer)

To the photocurable resin composition according to the present invention, an elastomer having a functional group may be added. By adding an elastomer having a functional group, the coating properties are improved and the strength of the resulting coating film is also expected to be improved. Examples of the trade name of such elastomer having a functional group include R-45HT and Poly bd HTP-9 (both of which are manufactured by Idemitsu Kosan Co., Ltd.); EPOLEAD PB3600 (manufactured by Daicel Chemical Industries, Ltd.); DENAREX R-45EPT (manufactured by Nagase ChemteX Corporation); and Ricon 130, Ricon 131, Ricon 134, Ricon 142, Ricon 150, Ricon 152, Ricon 153, Ricon 154, Ricon 156, Ricon 157, Ricon 100, Ricon 181, Ricon 184, Ricon 130MA8, Ricon 130MA13, Ricon 130MA20, Ricon 131MA5, Ricon 131MA10, Ricon 131MA17, Ricon 131MA20, Ricon 184MA6 and Ricon 156MA17 (all of which are manufactured by Sartomer). As the elastomer having a functional group, a polyester-based elastomer, a polyester urethane-based elastomer, a polyamide-based elastomer, a polyester amide-based elastomer, an acrylic elastomer or an olefin-based elastomer may also be employed. In addition, for example, a resin which is obtained by modifying some or all epoxy groups of an epoxy resin having various skeletons with a butadiene-acrylonitrile rubber whose terminals are both modified with carboxylic acid can also be employed. Moreover, for example, an epoxy-containing polybutadiene-based elastomer, an acryl-containing polybutadiene-based elastomer, a hydroxyl group-containing polybutadiene-based elastomer, a hydroxyl group-containing isoprene-based elastomer may also be employed. The content of the elastomer is preferably in the range of 3 to 124 parts by mass with respect to 100 parts by mass of the above-described (A) carboxyl group-containing resin. Further, the above-described elastomers may be used individually, or two or more thereof may be used in combination.

### (Mercapto Compound)

To the photocurable resin composition used in the present invention, a mercapto compound may also be added as required. By adding a mercapto compound, the PCT resistance and the HAST resistance are expected to be improved. This is believed to be attributable to an improvement in the adhesion properties.

Examples of the mercapto compound include mercaptoethanol, mercaptopropanol, mercaptobutanol, mercaptopropanediol, mercaptobutanediol, hydroxybenzenethiol and derivatives thereof, such as 1-butanethiol, butyl-3-mercaptopropionate, methyl-3-mercaptopropionate, 2,2-(ethylenedioxy)diethanethiol, ethanethiol, 4-methylbenzenethiol, dodecyl mercaptan, propanethiol, butanethiol, pentanethiol, 1-octanethiol, cyclopentanethiol, cyclohexanethiol, thioglycerol and 4,4-thiobisbenzenethiol.

Examples of the commercially available mercapto compound include BMPA, MPM, EHMP, NOMP, MBMP, STMP, TMMP, PEMP, DPMP and TEMPIC (which are manufactured by Sakai Chemical Industry Co., Ltd.); and KARENZ MT-PE1, KARENZ MT-BD1 and KARENZ NR1 (which are manufactured by Showa Denko K.K.).

Further, examples of a mercapto compound having a heterocyclic ring include mercapto-4-butyrolactone (synonym: 2-mercapto-4-butanolide), 2-mercapto-4-methyl-4-butyrolactone, 2-mercapto-4-ethyl-4-butyrolactone, 2-mercapto-4-butyrothiolactone, 2-mercapto-4-butyrolactam, N-methoxy-2-mercapto-4-butyrolactam, N-ethoxy-2-mercapto-4-butyrolactam, N-methyl-2-mercapto-4-butyrolactam, N-ethyl-2-mercapto-4-butyrolactam, N-(2-methoxy)ethyl-2-mercapto-4-butyrolactam, N-(2-ethoxy)ethyl-2-mercapto-4-butyrolactam, 2-mercapto-5-valerolactone, 2-mercapto-5-valerolactam, N-methyl-2-mercapto-5-valerolactam, N-ethyl-2-mercapto-5-valerolactam, N-(2-methoxy)ethyl-2-mercapto-5-valerolactam, N-(2-ethoxy)ethyl-2-mercapto-5-valerolactam, 2-mercaptobenzothiazole, 2-mercapto-5-methylthio-thiadiazole, 2-mercapto-6-hexanolactam, 2,4,6-trimercapto-s-triazine (manufactured by Sankyo Kasei Co., Ltd.: trade name “ZISNET F”), 2-dibutylamino-4,6-dimercapto-s-triazine (manufactured by Sankyo Kasei Co., Ltd.: trade name “ZISNET DB”) and 2-anilino-4,6-dimercapto-s-triazine (manufactured by Sankyo Kasei Co., Ltd.: trade name “ZISNET AF”).

Thereamong, 2-mercaptobenzoimidazole, 2-mercaptobenzoxazole, 2-mercaptobenzothiazole (trade name. ACCEL M; manufactured by Kawaguchi Chemical Industry Co., Ltd.), 3-mercapto-4-methyl-4H-1,2,4-triazole, 5-methyl-1,3,4-thiadiazole-2-thiol and 1-phenyl-5-mercapto-1H-tetrazole are preferred.

The content of such mercapto compound is appropriately 0.01 parts by mass to 10.0 parts by mass, more preferably 0.05 parts by mass to 5 parts by mass, with respect to 100 parts by mass of the above-described (A) carboxyl group-containing resin. When the content is less than 0.01 parts by mass, an improvement in the adhesion properties is not observed as an effect of adding a mercapto compound, while when the content is higher than 10.0 parts by mass, there may be caused a defect in the development of the photocurable resin composition and a reduction in the range where drying can be controlled; therefore, such a content of mercapto compound is not preferred. The above-described mercapto compounds may be used individually, or two or more thereof may be used in combination.

### (Coloring Agent)

Further, in the photocurable resin composition according to the present invention, a coloring agent may be blended. As the coloring agent, a commonly used and known coloring agent of red, blue, green, yellow or the like may be employed, and it may be any pigment, stain or dye. Specific examples of the coloring agent include those assigned with the following Color Index numbers (C.I.; issued by The Society of Dyers and Colourists). Here, from the standpoints of reducing the environmental stress and the effects on human body, it is preferred that the coloring agent contain no halogen.

### Red Coloring Agent:

Examples of red coloring agent include monoazo-type, disazo-type, azo lake-type, benzimidazolone-type, perylene-type, diketopyrrolopyrrole-type, condensed azo-type, anthraquinone-type and quinacridone-type red coloring agents, and specific examples thereof include the followings.

Monoazo-type: Pigment Red 1, 2, 3, 4, 5, 6, 8, 9, 12, 14, 15, 16, 17, 21, 22, 23, 31, 32, 112, 114, 146, 147, 151, 170, 184, 187, 188, 193, 210, 245, 253, 258, 266, 267, 268 and 269.

Disazo-type: Pigment Red 37, 38 and 41.

Monoazo lake-type: Pigment Red 48:1, 48:2, 48:3, 48:4, 49:1, 49:2, 50:1, 52:1, 52:2, 53:1, 53:2, 57:1, 58:4, 63:1, 63:2, 64:1 and 68.

Benzimidazolone-type: Pigment Red 171, Pigment Red 175, Pigment Red 176, Pigment Red 185 and Pigment Red 208.

Perylene-type: Solvent Red 135, Solvent Red 179, Pigment Red 123, Pigment Red 149, Pigment Red 166, Pigment Red 178, Pigment Red 179, Pigment Red 190, Pigment Red 194 and Pigment Red 224.

Diketopyrrolopyrrole-type: Pigment Red 254, Pigment Red 255, Pigment Red 264, Pigment Red 270 and Pigment Red 272.

Condensed azo-type: Pigment Red 220, Pigment Red 144, Pigment Red 166, Pigment Red 214, Pigment Red 220, Pigment Red 221 and Pigment Red 242.

Anthraquinone-type: Pigment Red 168, Pigment Red 177, Pigment Red 216, Solvent Red 149, Solvent Red 150, Solvent Red 52 and Solvent Red 207.

Quinacridone-type: Pigment Red 122, Pigment Red 202, Pigment Red 206, Pigment Red 207 and Pigment Red 209.

### Blue Coloring Agent:

Examples of blue coloring agent include phthalocyanine-type and anthraquinone-type blue coloring agents and examples of pigment-type blue coloring agent include those compounds that are classified into pigment. Specific examples include Pigment Blue 15, Pigment Blue 15:1, Pigment Blue 15:2, Pigment Blue 15:3, Pigment Blue 15:4, Pigment Blue 15:6, Pigment Blue 16 and Pigment Blue 60.

As a stain-type blue coloring agent, for example, Solvent Blue 35, Solvent Blue 63, Solvent Blue 68, Solvent Blue 70, Solvent Blue 83, Solvent Blue 87, Solvent Blue 94, Solvent Blue 97, Solvent Blue 122, Solvent Blue 136, Solvent Blue 67 and Solvent Blue 70 can be used. In addition to the above-described ones, a metal-substituted or unsubstituted phthalocyanine compound can be used as well.

### Green Coloring Agent:

Similarly, examples of green coloring agent include phthalocyanine-type, anthraquinone-type and perylene-type green coloring agents and specifically, for example, Pigment Green 7, Pigment Green 36, Solvent Green 3, Solvent Green 5, Solvent Green 20 and Solvent Green 28 can be used. In addition to the above-described ones, a metal-substituted or unsubstituted phthalocyanine compound can be used as well.

### Yellow Coloring Agent:

Examples of yellow coloring agent include monoazo-type, disazo-type, condensed azo-type, benzimidazolone-type, isoindolinone-type and anthraquinone-type yellow coloring agents and specific examples thereof include the followings.

Anthraquinone-type: Solvent Yellow 163, Pigment Yellow 24, Pigment Yellow 108, Pigment Yellow 193, Pigment Yellow 147, Pigment Yellow 199 and Pigment Yellow 202.

Isoindolinone-type: Pigment Yellow 110, Pigment Yellow 109, Pigment Yellow 139, Pigment Yellow 179 and Pigment Yellow 185.

Condensed azo-type: Pigment Yellow 93, Pigment Yellow 94, Pigment Yellow 95, Pigment Yellow 128, Pigment Yellow 155, Pigment Yellow 166 and Pigment Yellow 180.

Benzimidazolone-type: Pigment Yellow 120, Pigment Yellow 151, Pigment Yellow 154, Pigment Yellow 156, Pigment Yellow 175 and Pigment Yellow 181.

Monoazo-type: Pigment Yellow 1, 2, 3, 4, 5, 6, 9, 10, 12, 61, 62, 62:1, 65, 73, 74, 75, 97, 100, 104, 105, 111, 116, 167, 168, 169, 182 and 183.

Disazo-type: Pigment Yellow 12, 13, 14, 16, 17, 55, 63, 81, 83, 87, 126, 127, 152, 170, 172, 174, 176, 188 and 198.

In addition to the above, in order to adjust the color tone, for example, a violet, orange, brown and/or black coloring agent(s) may also be added.

Specific examples of such coloring agent include Pigment Violet 19, 23, 29, 32, 36, 38 and 42, Solvent Violet 13 and 36, C.I. Pigment Orange 1, C.I. Pigment Orange 5, C.I. Pigment Orange 13, C.I. Pigment Orange 14, C.I. Pigment Orange 16, C.I. Pigment Orange 17, C.I. Pigment Orange 24, C.I. Pigment Orange 34, C.I. Pigment Orange 36, C.I. Pigment Orange 38, C.I. Pigment Orange 40, C.I. Pigment Orange 43, C.I. Pigment Orange 46, C.I. Pigment Orange 49, C.I. Pigment Orange 51, C.I. Pigment Orange 61, C.I. Pigment Orange 63, C.I. Pigment Orange 64, C.I. Pigment Orange 71, C.I. Pigment Orange 73, C.I. Pigment Brown 23, C.I. Pigment Brown 25, C.I. Pigment Black 1 and C.I. Pigment Black 7.

The above-described coloring agents may be blended as appropriate and the content thereof is preferably not higher than 10 parts by mass, more preferably 0.1 to 5 parts by mass, with respect to 100 parts by mass of the above-described (A) carboxyl group-containing resin or the thermosetting component.

### (Organic Solvent)

Further, the photocurable resin composition according to the present invention may also comprise an organic solvent for the purpose of synthesizing the above-described carboxyl group-containing resin, preparing the composition or adjusting the viscosity for coating the composition onto a substrate or a carrier film.

Examples of such an organic solvent include ketones, aromatic hydrocarbons, glycol ethers, glycol ether acetates, esters, alcohols, aliphatic hydrocarbons and petroleum-based solvents. More specific examples thereof include ketones such as methyl ethyl ketone and cyclohexanone; aromatic hydrocarbons such as toluene, xylene and tetramethylbenzene; glycol ethers such as cellosolve, methylcellosolve, butylcellosolve, carbitol, methylcarbitol, butylcarbitol, propylene glycol monomethyl ether, dipropylene glycol monomethyl ether, dipropylene glycol diethyl ether and triethylene glycol monoethyl ether; esters such as ethyl acetate, butyl acetate, dipropylene glycol methyl ether acetate, propylene glycol methyl ether acetate, propylene glycol ethyl ether acetate and propylene glycol butyl ether acetate; alcohols such as ethanol, propanol, ethylene glycol and propylene glycol; aliphatic hydrocarbons such as octane and decane; and petroleum-based solvents such as petroleum ether, petroleum naphtha, hydrogenated petroleum naphtha and solvent naphtha. These organic solvents may be used individually, or two or more thereof may be used in combination.

The photocurable resin composition according to the present invention may further contain, as required, a known additive(s) such as at least one of antioxidants (e.g. radical scavengers and peroxide decomposers), ultraviolet absorbers, adhesion-promoting agents, thickening agents (e.g. fine powder silica, organic bentonite and montmorillonite), antifoaming agents (e.g. silicone-based, fluorine-based and macromolecular-based antifoaming agents) and leveling agents, silane coupling agents (e.g. imidazole-based, thiazole-based and triazole-based silane coupling agents), corrosion inhibitors and flame retardants.

The photocurable resin composition according to the present invention is, for example, after being adjusted with the above-described organic solvent to have a viscosity suitable for a coating method, applied onto a substrate by a dip coating method, a flow coating method, a roll coating method, a bar coater method, a screen printing method, a curtain coating method or the like and then heated at a temperature of about 60 to 100° C. to dry the organic solvent contained in the composition by evaporation (predrying), thereby a tack-free coating film can be formed. Further, in cases where the above-described composition is coated and dried on a carrier film and the resulting film is then rolled up to obtain a dry film, a resin insulation layer can be formed by pasting the dry film onto a substrate using a laminator or the like such that the photocurable resin composition layer and the substrate are in contact with each other and then removing the carrier film.

Examples of the above-described substrate include, in addition to printed wiring boards and flexible printed wiring boards that are formed with a wiring in advance, copper-clad laminates of all grades (e.g. FR-4), for example, copper-clad laminates for high-frequency wiring that are composed of a material such as paper phenol, paper epoxy, glass fabric epoxy, glass polyimide, glass fabric/nonwoven epoxy, glass fabric/paper epoxy, synthetic fiber epoxy, fluorine-polyethylene-polyphenylene ether or polyphenylene oxide-cyanate ester; other polyimide films; PET films; glass substrates; ceramic substrates; and wafer plates.

The drying by evaporation of the photocurable resin composition according to the present invention, which is done after applying the composition onto a substrate, can be carried out using a hot air circulation-type drying oven, an IR oven, a hot plate, a convection oven or the like (a method in which a dryer equipped with a heat source utilizing a steam air-heating system is employed to bring a hot air inside the dryer into contact against the composition or a method in which a hot air is blown against the substrate via a nozzle).

After applying the photocurable resin composition according to the present invention and drying the solvent by evaporation, by exposing the resulting coating film to a light (irradiation with an active energy beam), the exposed area (the part irradiated with the active energy beam) is cured. Further, a resist pattern is formed by selectively exposing the resultant to an active energy beam through a patterned photomask by a contact (or non-contact) method or directly exposing the resultant to a pattern using a laser direct exposure apparatus and then developing the resulting non-exposed part with a dilute aqueous alkaline solution (for example, 0.3 to 3 wt % aqueous sodium carbonate solution).

The exposure apparatus used for the above-described irradiation with an active energy beam may be any apparatus as long as it is equipped with a high-pressure mercury lamp, an ultra-high-pressure mercury lamp, a metal halide lamp, a mercury short arc lamp or the like by which an ultraviolet ray is irradiated in the range of 350 to 450 nm. Further, a direct imaging apparatus (for example, a laser direct imaging apparatus which utilizes a laser to directly draw an image based on CAD data transmitted from a computer) can be used as well. The laser source of the direct imaging apparatus may either be a gas laser or a solid-state laser as long as the laser light has a maximum wavelength in the range of 350 to 410 nm. The exposure dose for image formation varies depending on the film thickness and the like; however, in general, it may be in the range of 20 to 800 mJ/cm², preferably 20 to 600 mJ/cm².

The above-described development can be performed by, for example, a dipping method, a shower method, a spray method or a brush method. As a developing solution, an aqueous alkaline solution of potassium hydroxide, sodium hydroxide, sodium carbonate, potassium carbonate, sodium phosphate, sodium silicate, ammonia, amine or the like can be employed.

The photocurable resin composition according to the present invention is suitable as a permanent coating film of a printed wiring board and especially, as a solder resist and an interlayer insulation material.

### EXAMPLES

The present invention will now be described in more detail by way of examples and comparative examples. However, the present invention is not restricted thereto by any means.

### Synthesis Example 1

To 600 g of diethylene glycol monoethyl ether acetate, 1,070 g of o-cresol novolac-type epoxy resin (EPICLON N-695 manufactured by DIC Corporation; softening point: 95° C., epoxy equivalent: 214, average number of functional groups: 7.6), 360 g of acrylic acid and 1.5 g of hydroquinone were loaded, and the resulting mixture was heated to 100° C. with stirring and uniformly dissolved. Then, 4.3 g of triphenyl phosphine was further loaded and, after allowing the resultant to react for 2 hours by heating it to 110° C., the resultant was allowed to react for another 12 hours at 120° C. To the thus obtained reaction solution, 415 g of aromatic hydrocarbon (SOLVESSO 150) and 456.0 g of tetrahydrophthalic anhydride were loaded, and the resultant was allowed to react for 4 hours at 110° C. and then cooled to obtain a carboxyl group-containing resin having a solid acid value of 89 mg KOH/g and a solid content of 65%. This carboxyl group-containing resin is hereinafter referred to as “Resin Solution A-1”.

### Synthesis Example 2

To an autoclave equipped with a thermometer, a nitrogen and alkylene oxide introduction device and a stirring device, 119.4 of a novolac-type cresol resin (manufactured by Showa Denko K.K., trade name “Shonol CRG951”; OH equivalent: 119.4), 1.19 g of potassium hydroxide and 119.4 g of toluene were loaded, and the atmosphere inside the system was replaced with nitrogen with stirring and then heated. Subsequently, 63.8 g of propylene oxide was slowly added dropwise and the resultant was allowed to react for 16 hours at a temperature of 125 to 132° C. and a pressure of 0 to 4.8 kg/cm². Thereafter, the system was cooled to room temperature and 1.56 g of 89% phosphoric acid was added and mixed with the thus obtained reaction solution to neutralize potassium hydroxide, thereby obtaining a propylene oxide reaction solution of a novolac-type cresol resin having a non-volatile content of 62.1% and a hydroxyl value of 182.2 g/eq. In this reaction solution, an average of 1.08 mol of alkylene oxide was added per 1 equivalent of phenolic hydroxyl group. To a reaction vessel equipped with a stirrer, a thermometer and an air blowing tube, 293.0 g of the thus obtained alkylene oxide reaction solution of the novolac-type cresol resin, 43.2 g of acrylic acid, 11.53 g of methanesulfonic acid, 0.18 g of methylhydroquinone and 252.9 g of toluene were loaded. While blowing air into the resulting mixture at a rate of 10 ml/min, the mixture was allowed to react for 12 hours at 110° C. with stirring. By this reaction, 12.6 of water was distilled out as an azeotropic mixture with toluene. Thereafter, the resultant was cooled to room temperature and the thus obtained reaction solution was neutralized with 35.35 g of 15% aqueous sodium hydroxide solution and then washed with water. Subsequently, toluene was replaced with 118.1 g of diethylene glycol monoethyl ether acetate and distilled out using an evaporator to obtain a novolac-type acrylate resin solution. Next, 332.5 g of the thus obtained novolac-type acrylate resin solution and 1.22 g of triphenyl phosphine were loaded to a reaction vessel equipped with a stirrer, a thermometer and an air blowing tube. While blowing air to the resulting mixture at a rate of 10 ml/min, 60.8 g of tetrahydrophthalic anhydride was gradually added with stirring, and the resultant was allowed to react for 6 hours at a temperature of 95 to 101° C. As a result, a carboxyl group-containing resin having a solid acid value of 88 mg KOH/g and a solid content of 71% was obtained. This carboxyl group-containing resin is hereinafter referred to as “Resin Solution A-2”.

The above-described resin solutions were formulated as shown in Table 1 (parts by mass) and, after pre-mixing the respective formulations with a stirrer, the resultants were each kneaded using a 3-roll mill to prepare photocurable resin compositions of Examples 1 to 6 and Comparative Examples 1 to 6.

It is noted here that, when the degree of dispersion was evaluated for the thus obtained photocurable resin compositions based on the particle size measurement performed by a grind meter manufactured by Erichsen, it was found to be 15 μm or less for all of the photocurable resin compositions.

TABLE 1

| | | | | | | | Com- | Com- | Com- | Com- | Com- | Com- |
|---|---|---|---|---|---|---|---|---|---|---|---|---|
| | | | | | | | parative | parative | parative | parative | parative | parative |
| | Exam- | Exam- | Exam- | Exam- | Exam- | Exam- | Exam- | Exam- | Exam- | Exam- | Exam- | Exam- |
| Formulation Component | ple 1 | ple 2 | ple 3 | ple 4 | ple 5 | ple 6 | ple 1 | ple 2 | ple 3 | ple 4 | ple 5 | ple 6 |
| Resin Solution A-1 | 154 | — | — | — | — | — | 154 | 154 | — | — | — | — |
| Resin Solution A-2 | — | 141 | 141 | 141 | 141 | 141 | — | — | 141 | 141 | 141 | 141 |
| Photopolymerization initiator B-1 | 10 | 10 | 10 | 10 | 5 | 10 | — | 15 | 5 | — | — | 10 |
| Photopolymerization initiator B-2 | — | — | — | — | 3 | — | — | — | — | — | — | — |
| Photopolymerization initiator B-3 | 0.2 | 0.2 | 0.2 | 0.2 | 0.2 | 0.2 | — | — | — | 1.0 | 0.2 | 0.2 |
| Photopolymerization initiator B-4 | — | — | — | — | — | — | 15 | — | 10 | — | 10 | — |
| Polymerization inhibitor C-1 | 0.1 | 0.1 | 0.1 | — | 0.1 | 0.1 | 0.1 | 0.1 | 0.1 | 0.1 | 0.1 | — |
| Polymerization inhibitor C-2 | — | — | — | 1.0 | 0.5 | 0.5 | — | — | — | — | — | — |
| Filler D-1 | 80 | — | 80 | 80 | 80 | 50 | 80 | 80 | 80 | 80 | 80 | 80 |
| Filler D-2 | — | — | — | — | — | 30 | — | — | — | — | — | — |
| Filler D 3 | — | — | — | — | — | 10 | — | — | — | — | — | — |
| Photosensitive monomer*¹ | 20 | 20 | 20 | 20 | 20 | 20 | 20 | 20 | 20 | 20 | 20 | 20 |
| Thermosetting resin*² | 25 | 25 | 25 | 25 | 25 | 25 | 25 | 25 | 25 | 25 | 25 | 25 |
| Thermosetting resin*³ | 15 | 15 | 15 | 15 | 15 | 15 | 15 | 15 | 15 | 15 | 15 | 15 |
| Thermosetting catalyst*⁴ | 5 | 5 | 5 | 5 | 5 | 5 | 5 | 5 | 5 | 5 | 5 | 5 |
| Pigment*⁵ | 1 | 1 | 1 | 1 | 1 | 1 | 1 | 1 | 1 | 1 | 1 | 1 |
| Pigment*⁶ | 0.5 | 0.5 | 0.5 | 0.5 | 0.5 | 0.5 | 0.5 | 0.5 | 0.5 | 0.5 | 0.5 | 0.5 |
| Silicone-based antifoaming agent | 3 | 3 | 3 | 3 | 3 | 3 | 3 | 3 | 3 | 3 | 3 | 3 |
| Organic solvent*⁷ | 5 | 5 | 5 | 5 | 5 | 5 | 5 | 5 | 5 | 5 | 5 | 5 |

Photopolymerization initiator B-1: 2,4,6-trimethylbenzoin diphenylphosphine oxide
Photopolymerization initiator B-2: bis(2,4,6-trimethylbenzoyl)phenyl phosphine
Photopolymerization initiator B-3: bis(η5-2,4-cyclopentadiene-1-yl)-bis(2,6-difluoro-3-(1H-pyrrole-1-yl)-phenyl)titanium
Photopolymerization initiator B-4: 2-benzyl-2-dimethylamino-1-(4-morpholinophenyl)-butanone-1
Polymerization inhibitor C-1: 4-methoxy-1-naphthol; QUINO POWER MNT manufactured by Kawasaki Kasei Chemicals, Ltd.
Polymerization inhibitor C-2: phenothiazine manufactured by Seiko Chemical Co., Ltd.
Filler D-1: barium sulfate; B-30 manufactured by Sakai Chemical Industry Co., Ltd.
Filler D-2: silica; SO-E2 manufactured by Admatechs Co., Ltd.
Filler D-3: talc; SG-2000 manufactured by Nippon Talc Co., Ltd.
*¹Dipentaerythritol hexaacrylate
*²Phenol novolac-type epoxy resin
*³Triglycidyl isocyanurate
*⁴Melamine
*⁵Pigment Blue 15:3
*⁶Pigment Yellow 147
*⁷Dipropylene glycol monomethyl ether

### (Evaluation of Properties)

The above-described photocurable resin compositions of Examples and Comparative Examples are each applied onto the entire surface of a substrate by screen printing. The resulting substrates were dried for 30 minutes in an 80° C. hot air circulation-type drying oven and then allowed to cool to room temperature. Thereafter, using an exposure apparatus equipped with a high-pressure mercury lamp (mercury short arc lamp-equipped exposure apparatus; manufactured by ORC Manufacturing Co., Ltd.), each of the thus obtained substrates was exposed at an optimum exposure dose. The resulting substrates were then each developed with a developing solution (1% by mass aqueous sodium carbonate solution) for 60 seconds at a temperature of 30° C. and a spray pressure of 0.2 MPa, thereby forming a pattern. Further, the substrates were each irradiated with ultraviolet light in a UV conveyor furnace at a cumulative exposure dose of 1,000 mJ/cm² and subsequently cured by heating at 160° C. for 60 minutes. The properties of thus obtained printed substrates (evaluation substrates) were evaluated as follows. The optimum exposure dose was defined as an exposure dose obtained when the substrate was exposed via a step tablet (T4105C manufactured by Stouffer Industries, Inc.) and the residual step tablet after the development had 8 steps.

### (Resolution)

Using a negative pattern having a via opening size of 60 μm as an evaluation negative mask, an opening pattern of each photocurable resin composition was formed on a copper foil substrate. An opening formed on the thus obtained evaluation substrate was observed under a scanning electron microscope at a magnification of ×1,000 and the diameter thereof was measured at the bottom part to evaluate the resolution based on the following criteria.

⊚: The diameter was larger than 55 μm but not larger than 60 μm.

∘: The diameter was larger than 50 μm but not larger than 55 μm.

x: The diameter was 50 μm or smaller.

### (Adhesion)

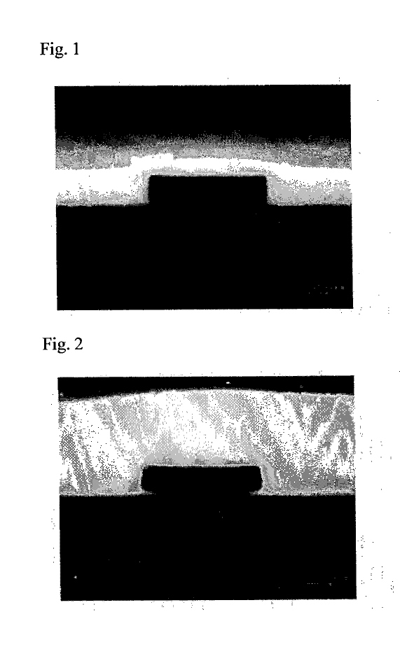

Using a negative pattern having a line width of 100 μm as an evaluation negative mask, a line pattern of each photocurable resin composition was formed on a substrate having a surface roughness (Ra) of 700 nm. The cross-sectional shape of a line formed on the thus obtained evaluation substrate was observed under a light microscope to evaluate the adhesion based on the following criteria. FIG. 1 is a photograph showing one exemplary case where no peeling was observed and FIG. 2 is a photograph showing one exemplary case where peeling was observed. The photographs of FIGS. 1 and 2 both show the cross-sectional shape of the line pattern of a photocurable resin composition and they were taken by a camera mounted on a light microscope. In the photograph showing peeling, a condition where both edges of the line are lifted is seen.

∘: No peeling was observed.

x: Peeling was observed.

### (HAST Resistance)

On a BT substrate having a comb-shaped electrode (line/space=50 μm/50 μm) formed thereon, a cured coating film of each photocurable resin composition was formed to prepare an evaluation substrate. This evaluation substrate was placed in an incubator having an atmosphere with a temperature of 130° C. and a humidity of 85%, and a voltage of 12 V was charged thereto to perform a 168-hour HAST test in the incubator. After 168 hours, the insulation resistance value within the incubator was evaluated based on the following criteria.

∘: over 10⁸Ω

Δ: 10⁶ to 10⁸Ω

x: less than 10⁶Ω

### (Stability in Working Environment)

The photocurable resin compositions of Examples 1 to 6 and Comparative Examples 1 to 6 were each applied onto the entire surface of a copper foil substrate by screen printing. The resulting substrates were dried for 30 minutes in an 80° C. hot air circulation-type drying oven and then allowed to cool to room temperature. After leaving the substrates to stand for 12 hours in a laboratory having yellow lamp lighting and a room temperature of 25° C., each substrate was developed with a developing solution (1% by mass aqueous sodium carbonate solution) for 60 seconds at a temperature of 30° C. and a spray pressure of 0.2 MPa. The thus developed substrates were evaluated based on the following criteria. Formation of residue indicates that photosetting reaction progressed under the yellow lamp, which means that the stability is poor.

∘: No residue was formed.

Δ: A small amount of residue was formed.

x: Residue was formed.

TABLE 2

| | | | | | | | Com- | Com- | Com- | | | |
|---|---|---|---|---|---|---|---|---|---|---|---|---|
| Evaluation | Exam- | Exam- | Exam- | Exam- | Exam- | Exam- | parative | parative | parative | Comparative | Comparative | Comparative |
| result | ple 1 | ple 2 | ple 3 | ple 4 | ple 5 | ple 6 | Example 1 | Example 2 | Example 3 | Example 4 | Example 5 | Example 6 |
| Resolution | ◯ | ⊚ | ⊚ | ◯ | ⊚ | ◯ | ◯ | ◯ | ◯ | X | X | ◯ |
| Adhesion | ◯ | ◯ | ◯ | ◯ | ◯ | ◯ | X | X | X | ◯ | ◯ | ◯ |
| HAST | Δ | ◯ | ◯ | ◯ | ◯ | ◯ | X | X | ◯ | ◯ | ◯ | ◯ |
| resistance | | | | | | | | | | | | |
| Stability in | Δ | ◯ | ◯ | ◯ | ◯ | ◯ | ◯ | ◯ | ◯ | X | ◯ | X |
| working | | | | | | | | | | | | |
| environment | | | | | | | | | | | | |

As shown in Table 2, in all of Examples 1 to 6, the resolution and the adhesion were found to be excellent and there was no problem in the HAST resistance and the stability in working environment.

On the other hand, in the photocurable resin compositions of Comparative Examples 1 to 5 in which at least one of the acylphosphine oxide-based photopolymerization initiators and titanocene-based photopolymerization initiators was not used, at least either of the resolution and the adhesion was inferior as compared to the photocurable resin compositions of Examples. Furthermore, in the photocurable resin composition of Comparative Example 6 which contained no polymerization inhibitor, the stability in working environment was found to be inferior as compared to the photocurable resin compositions of Examples.

1. A photocurable resin composition comprising:
(A) a resin comprising a carboxyl group;
(B) an acylphosphine oxide-based photopolymerization initiator;
(C) a titanocene-based photopolymerization initiator;
(D) a photosensitive monomer; and
(E) a polymerization inhibitor.

2. The photocurable resin composition of claim 1, wherein the acylphosphine oxide-based photopolymerization initiator is a compound having a partial structure represented by Formula (I): 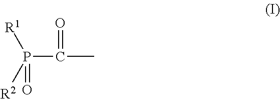
wherein R¹ and R² each independently represent a halogen atom, a linear or branched alkyl group having 1 to 6 carbon atoms, a linear or branched alkoxy group having 1 to 6 carbon atoms, a cycloalkyl group having 5 to 20 carbon atoms, an aryl group having 6 to 20 carbon atoms which is optionally substituted with one or more alkyl groups or alkoxy groups, or an arylcarbonyl group having 7 to 20 carbon atoms which is optionally substituted with one or more alkyl groups or alkoxy groups.

3. The photocurable resin composition of claim 1, wherein the titanocene-based photopolymerization initiator is a compound represented by Formula (II): 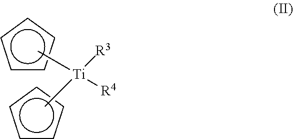
wherein R³ and R⁴ each independently represent an aryl group having 6 to 20 carbon atoms which is optionally substituted with at least one selected from the group consisting of a halogen atom, an alkyl group, an alkoxy group, an alkylcarbonyl group, an alkoxyalkylcarbonyl group, an aryl group and a heterocyclic group.

4. The photocurable resin composition of claim 1, wherein the titanocene-based photopolymerization initiator is a compound represented by the following formula

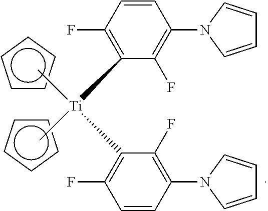

5. The photocurable resin composition of claim 1, wherein the polymerization inhibitor comprises at least one selected from the group consisting of a naphthalene derivative, a naphthoquinone and a naphthoquinone derivative.

6. The photocurable resin composition of claim 1, wherein the resin comprising a carboxyl group comprises, in reacted form, a phenol compound.

7. A dry film, obtained by coating and drying the photocurable resin composition of claim 1 on a film.

8. A cured product, obtained by curing the photocurable resin composition of claim 1, or by curing a dry film obtained by coating and drying the photocurable resin composition.

9. A printed wiring board comprising the cured product of claim 8.

10. The photocurable resin composition of claim 1, wherein the resin comprising a carboxyl group has an acid value of 40 to 200 mg KOH/g.

11. The photocurable resin composition of claim 1, wherein the resin comprising a carboxyl group has an acid value of 45 to 120 mg KOH/g.

12. The photocurable resin composition of claim 1, wherein the resin comprising a carboxyl group has a weight-average molecular weight of 2000 to 150,000.

13. The photocurable resin composition of claim 1, wherein the resin comprising a carboxyl group has a weight-average molecular weight of 5000 to 100,000.

14. The photocurable resin composition of claim 1, comprising 20 to 60 mass % of the resin comprising a carboxyl group.

15. The photocurable resin composition of claim 1, comprising 30 to 50 mass % of the resin comprising a carboxyl group.

16. The photocurable resin composition of claim 1, comprising 0.5 to 50 parts by mass of the acylphosphine oxide-based photopolymerization initiator, with respect to 100 parts by mass of the resin comprising a carboxyl group.

17. The photocurable resin composition of claim 1, comprising 0.01 to 10 parts by mass of the titanocene-based photopolymerization initiator, with respect to 100 parts by mass of the resin comprising a carboxyl group.

18. The photocurable resin composition of claim 1, wherein a mass ratio of the acylphosphine oxide-based photopolymerization initiator to the titanocene-based photopolymerization initiator is in a range of 1:0.01 to 1:1.

19. The photocurable resin composition of claim 1, comprising 5 to 100 parts by mass of the photosensitive monomer, with respect to 100 parts by mass of the resin comprising a carboxyl group.

20. The photocurable resin composition of claim 1, comprising 0.01 to 5 parts by mass of the polymerization inhibitor, with respect to 100 parts by mass of the resin comprising a carboxyl group.
